(19) United States
(12) Patent Application Publication
(10) Pub. No.: US 2008/0237718 A1
(43) Pub. Date: Oct. 2, 2008

(54) METHODS OF FORMING HIGHLY ORIENTED DIAMOND FILMS AND STRUCTURES FORMED THEREBY

(76) Inventors: Vladimir Noveski, Chandler, AZ (US); Sujit Sharan, Chandler, AZ (US); Aleksandar Aleksov, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/694,626

(22) Filed: Mar. 30, 2007

(51) Int. Cl. H01L 27/12; H01L 21/8238

(52) U.S. Cl. 257/351; 438/154; 257/E21.632; 257/E27.111

(57) ABSTRACT

Methods and associated structures of forming a microelectronic device are described. Those methods may include forming a first HOD layer on a first side of a first silicon substrate, forming a CMOS region on a second side of the silicon substrate, forming amorphous silicon on the CMOS region, recrystallizing the amorphous silicon to form a first single crystal silicon layer, and forming a second HOD layer on the first single crystal silicon layer.

### BACKGROUND OF THE INVENTION

Multi core semiconductor processors are currently being produced by packaging of multiple chips on a parallel plane. This configuration allows for the design of a suitable thermal solution, however typically there will be a penalty to the total product size in an x-y plane. Heat transfer may pose a significant problem for product performance and reliability when the three-dimensional (3D) stacking of CMOS devices is applied for multi core product solution, although this is more elegant and space saving alternative.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1j represent structures according to an embodiment of the present invention.

FIG. 2 represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may include forming a first highly-oriented diamond (HOD) layer on a first side of a first silicon substrate, forming a CMOS region on a second side of the silicon substrate, forming amorphous silicon on the CMOS region, re-crystallizing the amorphous silicon to form a first single crystal silicon layer, and forming a second HOD layer on the first single crystal silicon layer. Methods of the present invention enable the 3D integration of multiple semiconductor microprocessors by direct integration of the CMOS devices, with a novel design and process, using highly oriented diamond (HOD) for interlayer passivation and heat spreading of silicon-based devices.

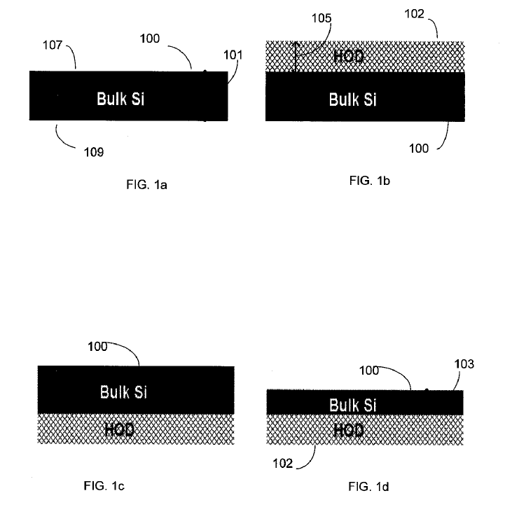

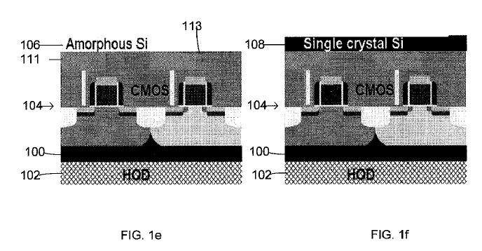

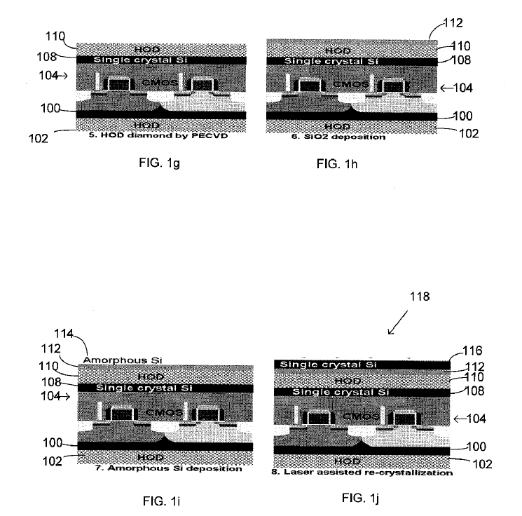

FIGS. 1a-1i illustrate an embodiment of a method of forming a microelectronic structure, such as a 3D stacked microelectronic structure, for example. FIG. 1a illustrates a cross-section of a portion of a substrate 100. The substrate 100 may be comprised of other semiconductor materials such as, but not limited to, silicon, silicon-on-insulator, germanium, as well as composite semiconductors (II-IV) and (III-V and/or III-Nitrides) such as indium antimonide, lead telluride, indium arsenide, indium phosphide, gallium arsenide, gallium antimonide, gallium nitride, silicon carbide, aluminum nitride,or combinations thereof. In one embodiment, the substrate 100 may comprise a thickness 101 of greater than about 40 microns.

In one embodiment, a first highly oriented diamond layer 102 (HOD) may be formed on a first side 107 of the substrate 100 (FIG. 1b). The first HOD layer 102 may be formed by plasma enhanced chemical vapor deposition (PECVD), for example, or other formation techniques suitable for the formation the first HOD layer. The thermal conductivity of the first HOD layer 102 may range from about 6-20 (W/cm deg) in some embodiments, and has a similar and compatible thermal expansion coefficient (about 3 vs about 1 (1/Kelvin) with silicon. The first HOD layer 102 may comprise a thermal conductivity of that is about 1000 times higher than conventional dielectric, such as are used in interlayer dielectric materials (ILD), for example. In one embodiment, the first HOD layer 102 may comprise a thickness 105 of about 200 to about 300 microns, but may vary according to the particular application.

In some embodiments, the high thermal conductivity of the first HOD layer 102 allows for a much higher heat flux in a radial direction as compared to conventional microelectronic materials. In some embodiments, the first HOD layer 102 can be grown on the substrate 100 silicon with high orientation and a high growth rate in a plasma enhanced CVD system. In some embodiments, the first HOD layer may comprise a diamond film oriented in one direction, either a (100) direction or a (001) direction.

In one embodiment, lattice parameters of grains of the first HOD layer 102 may comprise about 3 to about 4 angstroms, which is compatible with the lattice parameters of silicon (about 5.5 to about 5.7 angstroms). In one embodiment, the first HOD layer 102 can be patterned by an argon/oxygen plasma at temperatures that may vary from about room temperature to about 100 deg Celsius, with etch rates of the first HOD comprising about 25 microns per hour to about 40 microns per hour. In one embodiment, the first HOD layer 102 may comprise a heat dissipation structure, such as a heat spreader structure, and may replace the use of more conventional heat dissipation structures, such as but not limited to heat sinks, thereby minimizing space requirements for such heat dissipation structures on a microelectronic structure.

The substrate 100 may be flipped over (FIG. 1c) and a second side 109 of the substrate 100 may be thinned. In some embodiments, the substrate 100 may be thinned to a thickness 103 of about 20 microns to about 30 microns, utilizing conventional wafer thinning methods such as but not limited to fine slurry polishing. Front-end fabrication processing of device structures, such as CMOS structures, for example, may be performed on the second side 109 of the substrate 100 utilizing standard processing and patterning techniques, as are known in the art, to form a CMOS layer 104 (FIG. 1d). The CMOS layer 104 may comprise various components as are known in the art, such as but not limited to PMOS and NMOS devices, ILD layers, contacts, vias, metallic/conductive interconnect structures, etc.

In one embodiment, an amorphous dielectric layer (not shown) may be formed on the CMOS layer 104. In one embodiment, an amorphous silicon layer 106 may be formed on the CMOS layer 104 (FIG. 1e). In one embodiment, the amorphous silicon layer 106 may be disposed above and/or on a metal one layer, a nitride passivation layer (not shown) and an ILD layer 113. The amorphous silicon layer 106 may be formed according to any suitable technique, as is known in the art. The amorphous silicon layer 106 may be laser annealed (according to methods known in the art) to form a first single crystalline silicon layer 108 (FIG. 1f). In one embodiment, a laser assisted re-crystallization process may be employed, and a semiconductor quality single crystalline layer 108 may be formed.

A second HOD layer 110 (similar to the first HOD layer 102) may be formed on the single crystalline silicon layer 108 (FIG. 1g). The second HOD layer may serve as a passivation layer and/or a heat dissipation structure within a microelectronic structure. Another amorphous dielectric layer 112 may be optionally formed on the second HOD layer 110 (FIG. 1h), and a second amorphous silicon layer 114 may be formed on the second HOD layer 110 (FIG. 1i). The second amorphous silicon layer 114 may be laser annealed and recrystallized to form a second single crystalline silicon layer 116 (FIG. 1j) to form a microelectronic structure 118, such as a portion of a microprocessor, for example. Thus, the microelectronic structure 118 comprises an integrated heat sink disposed on the substrate 100 of the microelectronic structure 118.

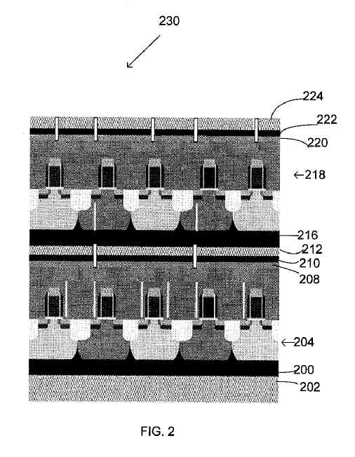

FIG. 2 depicts a 3d stacked microelectronic device 230. The 3D stacked microelectronic device 230 may comprise multiple layers of CMOS. Two layers are shown here, a first CMOS layer 204 and a second CMOS layer 218. The desired number of CMOS layers will depend upon the particular application requirements, such as but not limited to heat flux and device dimensions requirements. The 3d stacked microelectronic device 230 may comprise a first HOD layer 202 disposed on a silicon substrate 200, wherein the first HOD layer 202 may serve as a heat sink in some applications.

An optional dielectric layer 208 may be disposed on the first CMOS layer 204, a first single crystal silicon layer 210 may be disposed on the dielectric layer 208, a second HOD layer 212 may be disposed on the first single crystal silicon layer 210, and a second single crystal silicon layer 216 may be disposed on the second HOD layer 212. The second CMOS layer 218 may be disposed formed on the second single crystal silicon layer 216.

An additional oxide layer 220, a third single crystal silicon layer 222 and a third HOD 224 layer may be stacked, as desired. In some embodiments, thermal management and 3D stacking of CMOS devices may be optimized to achieve a minimum microchip size and optimum performance. Thus, the benefits of the embodiments of the present invention include, but are not limited to, improving the thermal budget on the device by the addition of HOD heat spreaders, which may also improve the mechanical integrity of the device.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices are well known in the art. Therefore, it is appreciated that the Figures provided herein illustrate only portions of an exemplary microelectronic structure that pertains to the practice of the present invention. Thus the present invention is not limited to the structures described herein.

What is claimed is:

1. A method comprising:
forming a first HOD layer on a first side of a first silicon substrate;
forming a CMOS region on a second side of the silicon substrate;
forming amorphous silicon on the CMOS;
recrystallizing the amorphous silicon to form a first single crystal silicon layer; and
forming a second HOD layer on the first single crystal silicon layer.

2. The method of claim 1 further comprising forming an oxide layer on the second HOD layer.

3. The method of claim 2 further comprising forming a second amorphous silicon layer on the second HOD layer, wherein the second amorphous silicon layer is recrystallized to form a second single crystal silicon layer.

4. The method of claim 3 further comprising forming a second CMOS region on the second single crystal silicon layer.

5. The method of claim 4 further comprising forming a third single crystal silicon layer on the second CMOS layer.

6. The method of claim 5 further comprising forming a third HOD layer on the second CMOS layer.

7. The method of claim 1 further comprising wherein the first HOD layer comprises a heat dissipating structure.

8. The method of claim 1 further comprising wherein the second side of the silicon substrate is polished after the first HOD layer is formed.

9. A structure comprising:
a first HOD layer disposed on a first side of a silicon substrate; and
a first CMOS layer disposed on a second side of the silicon substrate.

10. The structure of claim 9 further comprising:
a first single crystal silicon layer disposed on the first CMOS layer; and
a second HOD layer disposed on the first single crystal silicon layer.

11. The structure of claim 10 further comprising:
a second single crystal silicon layer disposed on the second HOD layer;
a second CMOS layer disposed on the third single crystal layer; and
a third HOD layer disposed on the second CMOS layer.

12. The structure of claim 9 further comprising wherein the first HOD layer comprises an integrated heat sink.

13. The structure of claim 11 wherein the first CMOS layer and the second CMOS layer each comprise a single layer of interconnect metal.

14. The structure of claim 9 wherein a thickness of the HOD layer comprises about 100 microns to about 200 microns.

15. The structure of claim 9 wherein the first, second and third HOD layers comprise one of a (100) and a (001) grain orientation.
